(19) United States
(12) Patent Application Publication
(10) Pub. No.: US 2010/0095192 A1
(43) Pub. Date: Apr. 15, 2010

(54) BERGER INVERT CODE ENCODING AND DECODING METHOD

(75) Inventor: Tsung-Chu HUANG, CHANGHUA CITY (TW)

Correspondence Address: BRIAN M. MCINNIS, 12th Floor, Ruttonjee House, 11 Duddell Street, Hong Kong, HK

(73) Assignee: NATIONAL CHANGHUA UNIVERSITY OF EDUCATION, CHANGHUA CITY (TW)

(21) Appl. No.: 12/403,382

(22) Filed: Mar. 13, 2009

(30) Foreign Application Priority Data
Oct. 14, 2008 (TW) 97139343

(51) Int. Cl. H03M 13/51

(52) U.S. Cl. 714/806; 341/94

(57) ABSTRACT

A Berger invert code encoding and decoding method is disclosed. The method includes steps: Selecting logic value 0 or 1 to represent the stable and unstable states respectively. Calculating the stable bit count and the unstable-bit count of the codeword. Checking whether the unstable bit count is larger than the stable bit count or not. Setting the Invert Bit to the unstable state for indicating the inversion when the unstable bit count is larger than the stable bit count. Resetting the Invert Bit to the stable state for indicating the non-inversion when the unstable bit count is not larger than the stable bit count. Concatenating the Invert Bit to the codeword as a new codeword.

### RELATED APPLICATIONS

This application claims priority to Taiwan Application Serial Number 97139343, filed Oct. 14, 2008, which is herein incorporated by reference.

### BACKGROUND OF THE INVENTION

1. Field of Invention

The present invention relates to an encoding/decoding method, and particularly relates to an encoding/decoding method of the Berger Code.

2. Description of Related Art

The first prior art reference about the Berger codes occurs in the article “A note on error detection codes for asymmetric channels” by J. M. Berger in volume 4 of Information and Control at pp. 68-73 in March 1961. In the later prior arts, the asymmetric channels can be generalized to data storage. All of them are related to a binary digital system where for each bit, the probability of an error from the unstable state to the stable state is higher than the probability of the opposite one. Particularly, the probability of an error from the stable state to the unstable state is zero in a fully asymmetric communication or storage system. The unstable state may be in a higher or lower voltage, current or other signals and can be represented in logic value 0 or 1 while the stable state can be represented in the alternative logic value.

To introduce the prior arts, FIG. 1 shows an implementation of the traditional Berger Codes applied in communication, where the stable and unstable states are respectively represented by logic values 0 and 1. An n-bit codeword w transmitted to an asymmetric communication channel 100 from the transmitter 110 to the receiver 120. The m-bit stable-bit count c is obtained by a parallel counter 111, represented as #0's for a 0's counter, and transmitted along with the codeword w as the check bits 112. While the data is received, the stable-bit count of the received codeword w′ is calculated again by a parallel counter 122 and compared with the received checkbits c′ by a comparator 123. If the binary number represented by the received checkbits 121 is less than the stable-bit count, i.e. c′<#0's(w′), the output 124 indicates an error.

Unidirectional fault detecting methods including the m-out-of-n codes, the two-rail codes and the Berger Codes have been used for more than 50 years in fully asymmetric communication systems. However, most previous work has been devoted to enhancing the totally self-checking (TSC), reducing the area overhead and decreasing the decoding time, but ignores the improvement of the reliability.

### SUMMARY OF THE INVENTION

A Berger invert code encoding and decoding method is disclosed. The method includes steps: Selecting logic value 0 or 1 to represent the stable and unstable states respectively. Calculating the stable bit count and the unstable-bit count of the codeword. Checking whether the unstable bit count is larger than the stable bit count or not. Setting the Invert Bit to the unstable state for indicating the inversion when the unstable bit count is larger than the stable bit count. Resetting the Invert Bit to the stable state for indicating the non-inversion when the unstable bit count is not larger than the stable bit count. Concatenating the Invert Bit to the codeword as a new codeword.

### BRIEF DESCRIPTION OF THE DRAWINGS

The invention can be more fully understood by reading the following detailed description of the embodiment, with reference made to the accompanying drawings as follows:

FIG. 1 is a circuit diagram view of the prior arts.

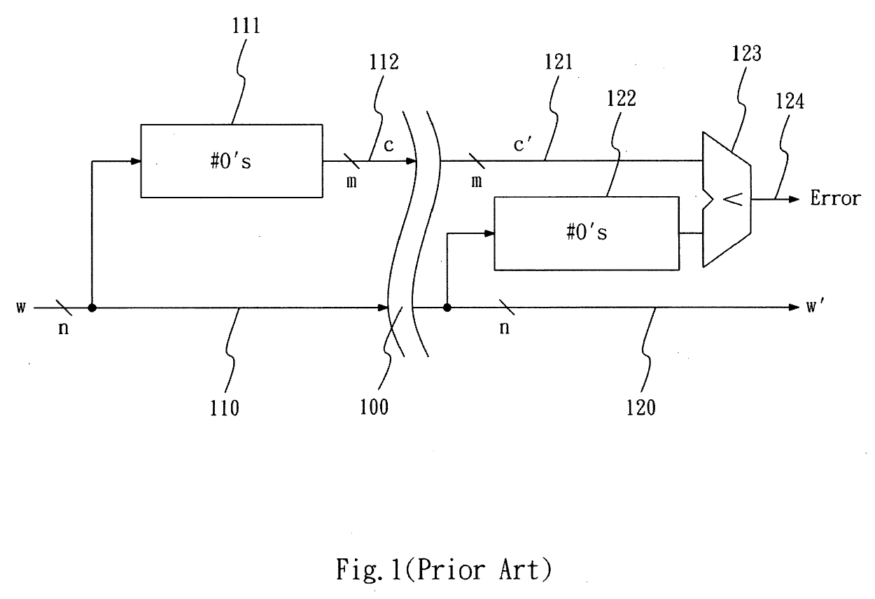

FIG. 2 is the flowchart diagram of the method of the invention.

FIG. 3 is the circuit diagram of one embodiment to realize the method shown in FIG. 2.

### DETAILED DESCRIPTION

### The Embodiment of the Method of the Invention

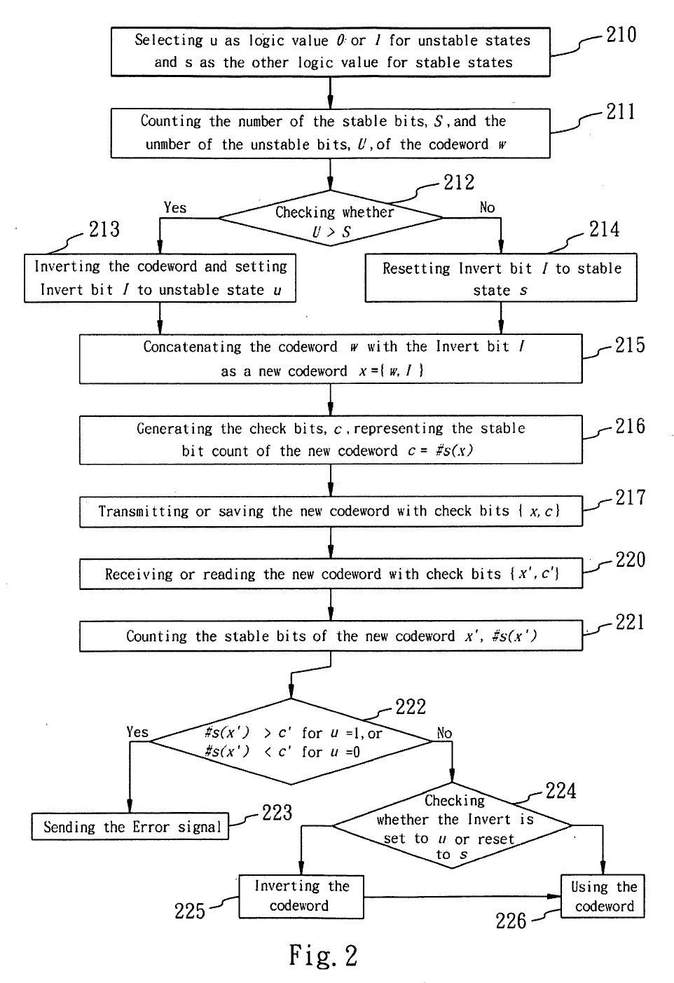

Refer to FIG. 2 for a flowchart diagram of the method of the present invention. The Berger Invert Code encoding and decoding method is applied to an error-asymmetric channel that can be also generalized to an asymmetric binary data transmission, communication or storage. In the asymmetric channel, the data is transferred or saved by a binary signal that can be the voltage, current, frequency or others, and the probabilities of error occurrence from one state to the other are not equal to each other. For usual applications, the probability of each bit disturbed from the stable state s to the unstable state n is much less than that in the other direction and particularly zero in a fully asymmetric channel.

The embodiment of the method in the present invention includes the steps of following:

First, as shown in step 210, the embodiment selects logic value 0 or 1 to represent the unstable state u and the other logic value for the stable state s.

Second, as shown in step 211, the embodiment calculates the stable bit count S and the unstable-bit count U of the n-bit codeword w. For convenience of description, let #b(w) represents the bit-b count in codeword w. Therefore, S=#s(w) and U=#u(w) in this step. Note that one of them can be easily obtained by each other with respect to S+U=n.

For most voltage-mode electronic systems, low voltage state is more stable than the high voltage state. Namely, in such a system, the high voltage state may be disturbed by hazard in the channel and be lowered thereof. The fully asymmetric communication system may recognize the bit as being in a low voltage state, and generate bit errors.

Third, as shown in step 212, the embodiment checks whether the unstable bit count U, is larger than the stable bit count S, U>S, or not. If the unstable bit count is larger than the stable bit count as shown in step 213, a flag bit, called the Invert Bit I, is set to the unstable state for indicating the inversion. Otherwise as shown in step 214, the Invert Bit I is reset to the stable state for indicating the non-inversion. The Invert Bit I is then concatenated to the codeword w as a new codeword x={I, w} for transmitting or storing in step 215.

The encoding method for the traditional Berger codes is then followed in steps 216-217 and decoding method in steps 220-223. Namely for the new codeword x, the stable-bit count is calculated in step 216, c=#s(x) and both of them, {c, x}, are transmitted to the channel or saved in a storage in step 217.

Similar to the traditional checker of the Berger codes, the checker receives or reads the codeword x′ with the associated checkbits c′ in step 220. The stable bit count #s(x′) is then calculated again in step 221 and compared with c′ in step 222. For most preferred applications where the unstable state is represented by logic value 1, the case #s(x′)>c′ will indicate an error in step 223. Once the unstable state is represented by logic value 0, the error should be indicated by #s(x′)<c′.

In the method of the present invention, the Invert bit will be separated from the received codeword to check the inversion in step 224. If the Invert bit indicated that the remaining codeword bits have been inverted, the remaining bits will be inverted again in step 225. Finally the recovered codeword is then used in the corresponding application as shown in step 226.

In the foregoing embodiment, the codewords with more unstable bits are transferred to those with less ones so that the error rate can then be reduced. Because the probability of the transitions is also lowered between successive codewords, about one quarter of power is also reduced.

### The Embodiment of the Apparatus to Achieve the Method

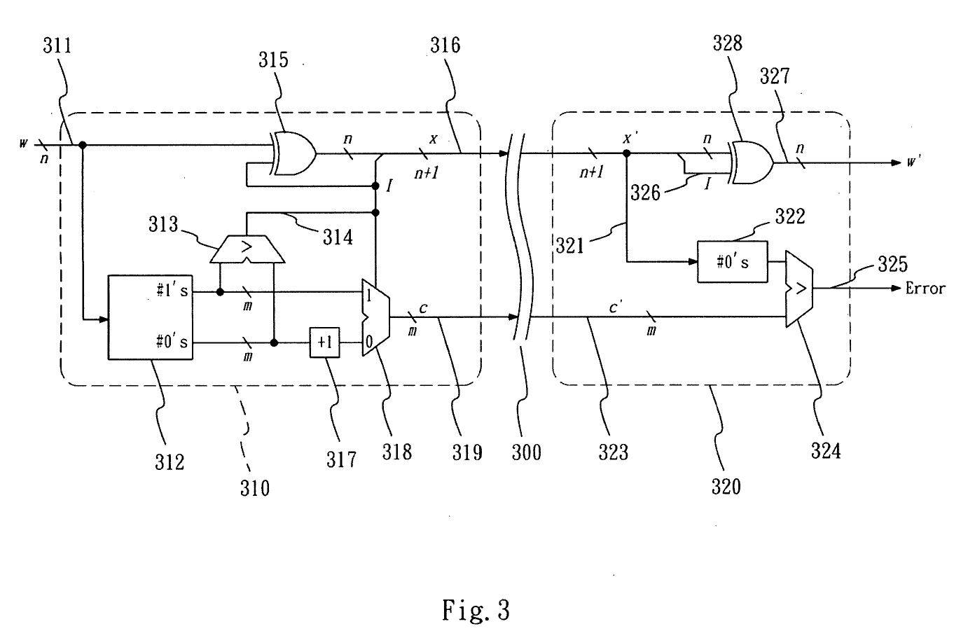

FIG. 3 shows an electronic schematic diagram for an embodiment of the apparatus where the unstable state ii is represented by logic value 1 and s=0 in the positive logic system. The codeword error rate and energy of the information can be improved through an error-asymmetric channel 300 from the transmitter 310 to the receiver 320.

First, the n-bit codeword w is inputted into 311. For convenience of explanation, two 6 bit codewords, w₁=“001000” and w₂=“101111” are taken as examples in difference cases.

Second, the 0's count and the 1's count are calculated in a parallel counter 312 which can be implemented by only a 1's counter for #1's along with a m-bit subtractor for #0's where m can be the ceiling number of log₂n.

Next, the 0's count and the 1's count are compared by an m-bit comparator 313 to generate the Invert Bit I at 314. In one case, I is reset to 0 because U=#1's (001000)=1 and S=n−U=5. In the other case, I is set to 1 since U=#1's(101111)=5 and S=n−U=1.

In the following step, the codeword w is inverted by the set of XOR gates 315 while I=1, otherwise, it will stay as is. Concatenated with the Invert Bit, the transmitted codeword x will be {I, w} at 316 if I=0, or {1, w̅} if I=1.

In the non-inverting case, due to the extra bit I=0, #0's(x) will be #0's(w)+1, therefore a simple increment circuit 317 is added. The checkbits c are chosen by the selector 318. For example 1, #0's(x)=#0's(0_{—}01000)=6 thus c will be 110₂.

For the inverting case, #0's(x)=#1's(w) is selected by the selector 318 as the checkbits c. For example 2, the submitted checkbits c will be 010₂ since #0's(x)=#1's(1_{—}010000).

When the codeword x′ at 321 are read from the storage or received from the channel, the 0's count is calculated again by the parallel counter 322 and then compared with the received checkbits c′ at 323 by a comparator 324. If the 0's count of the received codeword is larger than the binary number represented by the received checkbits, an error signal is sent out at 325. Taking the codeword w₁ as an example, either the 0's count increased by collapsing down the bit 1 in the received codewords, “0_{—}001000”, or the binary number of the received checkbits, c′=110₂, decreased by changing any one to zero in c′, the 0's count of the received codeword will be greater than the binary number of the checkbits. The error is then detected.

Otherwise, the Invert Bit split form the received codeword at 326 is used to recover the codeword to the recovered codeword w′ at 327 by the set of XOR gates 328. For instance in example 2, the received codeword will be x′=1_{—}010000 and the recovered codeword w′ can then be recovered to 101111=w by inverting 01000.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A Berger invert code encoding and decoding method comprising:
selecting logic value 0 or 1 to represent the stable and unstable states respectively;
calculating the stable bit count and the unstable-bit count of the codeword;
checking whether the unstable bit count is larger than the stable bit count or not;
setting the Invert Bit to the unstable state for indicating the inversion when the unstable bit count is larger than the stable bit count;
resetting the Invert Bit to the stable state for indicating the non-inversion when the unstable bit count is not larger than the stable bit count; and
concatenating the Invert Bit to the codeword as a new codeword.

2. The Berger invert code encoding and decoding method of claim 1, wherein the inversion is achieved by an encoder.

3. The Berger invert code encoding and decoding method of claim 2, wherein the encoder comprises a parallel counter for both 0's and 1's counts.

4. The Berger invert code encoding and decoding method of claim 3, wherein the parallel counter comprises a 0's counter and a 1's counter.

5. The Berger invert code encoding and decoding method of claim 3, wherein the parallel counter comprises 1's counter and a subtractor for generating the 0's count from the 1's counter.

6. The Berger invert code encoding and decoding method of claim 2, wherein the encoder comprises a comparator for deciding the inversion.

7. The Berger invert code encoding and decoding method of claim 2, wherein the encoder comprises a set of XOR gates for executing the inversion.

8. The Berger invert code encoding and decoding method of claim 2, wherein the encoder comprises an increment circuit and a selector.

9. The Berger invert code encoding and decoding method of claim 1, further comprising:
receiving the new codeword as a received codeword;
separating the received codeword into the Invert Bit and the recovered codeword; and
inverting the recovered codeword if the Invert Bit indicates the inversion.

10. The Berger invert code encoding and decoding method of claim 9, wherein the step of inverting the recovered codeword is achieved by a decoder.

11. The Berger invert code encoding and decoding method of claim 10, wherein the decoder comprises a conventional Berger code checker and a post-decoder.

12. The Berger invert code encoding and decoding method of claim 11, wherein the post-decoder separates the Invert Bit from the received codeword.

13. The Berger invert code encoding and decoding method of claim 11, wherein the post-encoder comprises a set of XOR gates for executing the step of inverting the separated codeword to the recovered codeword.
